(19) United States
(12) Patent Application Publication
(10) Pub. No.: US 2026/0052858 A1
(43) Pub. Date: Feb. 19, 2026

(54) DISPLAY DEVICE

(71) Applicant: Samsung Display Co., Ltd., Yongin-si (KR)

(72) Inventors: Min Kang, Yongin-si (KR); Jaewon Kim, Yongin-si (KR); Hyungjun Park, Yongin-si (KR); Hyunji Cha, Yongin-si (KR)

(21) Appl. No.: 19/295,877

(22) Filed: Aug. 11, 2025

(30) Foreign Application Priority Data
Aug. 14, 2024 (KR) 10-2024-0109111

(51) Int. Cl. H10K 59/131

(52) U.S. Cl. CPC H10K 59/131

(57) ABSTRACT

A display device includes a substrate including a display area including a corner portion, a connection portion, and a central portion, and a peripheral area surrounding at least a portion of the display area in plan view, a first display element in the corner portion, a second display element in the connection portion, a first pixel circuit unit in the corner portion, and electrically connected to the first display element, a second pixel circuit unit in the connection portion, and electrically connected to the second display element, and gate drivers arranged in a line along a first direction, a gate driver of the gate drivers being in the connection portion, overlapping at least a portion of the second pixel circuit unit, and electrically connected to the first pixel circuit unit.

### CROSS-REFERENCE TO RELATED APPLICATION

The present application claims priority to, and the benefit of, Korean Patent Application No. 10-2024-0109111, filed on Aug. 14, 2024, in the Korean Intellectual Property Office, the entire disclosure of which is incorporated herein by reference.

### BACKGROUND

### 1. Field

One or more embodiments relate to a display device.

### 2. Description of the Related Art

Display devices visually display data. Display devices may provide an image by using light-emitting diodes. The use of display devices has diversified, and various designs for improving the quality of display devices have been attempted.

### SUMMARY

One or more embodiments include a display device.

Additional aspects will be set forth in part in the description which follows and, in part, will be apparent from the description, or may be learned by practice of the presented embodiments of the disclosure.

According to one or more embodiments, a display device includes a substrate including a display area including a corner portion, a connection portion, and a central portion, and a peripheral area surrounding at least a portion of the display area in plan view, a first display element in the corner portion, a second display element in the connection portion, a first pixel circuit unit in the corner portion, and electrically connected to the first display element, a second pixel circuit unit in the connection portion, and electrically connected to the second display element, and gate drivers arranged in a line along a first direction, a gate driver of the gate drivers being in the connection portion, overlapping at least a portion of the second pixel circuit unit, and electrically connected to the first pixel circuit unit.

The first pixel circuit unit and the gate driver may be spaced apart in a second direction crossing the first direction.

The gate driver may be closest to the first pixel circuit unit of the gate drivers.

The first pixel circuit unit and the second pixel circuit unit may be at a layer above the gate driver.

The first display element may be provided in plurality, the first display elements including a 1st-1 display element at an uppermost part of the corner portion.

The first pixel circuit unit may be provided in plurality, the first pixel circuit units including a 1st-1 pixel circuit unit at the uppermost part of the corner portion, and electrically connected to the 1st-1 display element.

The gate drivers may include a first gate driver at an uppermost part of the connection portion, and electrically connected to the 1st-1 pixel circuit unit.

The gate drivers may be aligned in the first direction.

The display device may further include a clock line overlapping the gate drivers, and extending in the first direction.

The clock line may be configured to electrically connect the gate drivers to each other.

The gate driver may be electrically connected to the second pixel circuit unit.

The connection portion may be between the corner portion and another corner portion of the display area, wherein the central portion of the display area is inside the corner portion and the connection portion.

According to one or more embodiments, a display device includes a substrate including a display area including a corner portion, a connection portion, and a central portion, and a peripheral area surrounding at least a portion of the display area in plan view, a first display element in the corner portion, a second display element in the connection portion, a first pixel circuit unit in the corner portion, and electrically connected to the first display element, a second pixel circuit unit in the connection portion, and electrically connected to the second display element, and gate drivers arranged in a first direction, respectively offset from one another in a direction from the connection portion toward the corner portion, and including a gate driver in the connection portion, overlapping at least a portion of the second pixel circuit unit, and electrically connected to the first pixel circuit unit.

The gate driver may be closest to the first pixel circuit unit of the gate drivers in a second direction crossing the first direction.

The first display element may be provided in plurality, the first display elements including a 1st-1 display element at an uppermost part of the corner portion.

The first pixel circuit unit may be provided in plurality, the first pixel circuit units including a 1st-1 pixel circuit unit at the uppermost part of the corner portion, and electrically connected to the 1st-1 display element.

The gate drivers may include a first gate driver at an uppermost part of the connection portion, and electrically connected to the 1st-1 pixel circuit unit.

The gate drivers may be respectively offset in a direction toward the corner portion with respect to the first gate driver.

The display device may further include a clock line overlapping the gate drivers, and having a stepped shape in plan view.

The clock line may be configured to electrically connect the gate drivers to each other.

According to one or more embodiments, an electronic device includes a display device including a substrate including a display area including a corner portion, a connection portion, and a central portion, and a peripheral area surrounding at least a portion of the display area in plan view, a first display element in the corner portion, a second display element in the connection portion, a first pixel circuit unit in the corner portion, and electrically connected to the first display element, a second pixel circuit unit in the connection portion, and electrically connected to the second display element, and gate drivers arranged in a line along a first direction, a gate driver of the gate drivers being in the connection portion, overlapping at least a portion of the second pixel circuit unit, and electrically connected to the first pixel circuit unit.

### BRIEF DESCRIPTION OF THE DRAWINGS

The above and other aspects of certain embodiments of the disclosure will be more apparent from the following description taken in conjunction with the accompanying drawings, in which:

FIG. 1A is a schematic perspective view of a display device according to one or more embodiments;

FIG. 1B is a schematic plan view of a display device according to one or more embodiments;

FIGS. 2 and 3 are equivalent circuit diagrams of a pixel that may be included in a display device according to one or more embodiments;

FIG. 4 is a schematic cross-sectional view of a display device;

FIG. 5 schematically shows an enlarged plan view of a portion of a display area of a display device;

FIG. 6 schematically shows a portion of a display area of a display device;

FIG. 7 is a schematic cross-sectional view of the display area of the display device of FIG. 5, taken along the line II-II′ of FIG. 5; and

FIG. 8 schematically shows an enlarged plan view of a portion of a display area of a display device.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

In the drawings, the relative sizes of elements, layers, and regions may be exaggerated for clarity and/or descriptive purposes. In other words, because the sizes and thicknesses of elements in the drawings are arbitrarily illustrated for convenience of description, the disclosure is not limited thereto. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “over,” “higher,” “upper side,” “side” (e.g., as in “sidewall”), and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component (e.g., an apparatus, a device, a circuit, a wire, an electrode, a terminal, a conductive film, etc.) is referred to as being “formed on,” “on,” “connected to,” or “(operatively, functionally, or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a transistor, a resistor, an inductor, a capacitor, a diode and/or the like. Accordingly, a connection is not limited to the connections illustrated in the drawings or the detailed description and may also include other types of connections. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XY, YZ, and XZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B”may include A, B, or A and B.

Similarly, expressions such as “at least one of,” “a plurality of,” “one of,” and other prepositional phrases, when preceding a list of elements, modify the entire list of elements and do not modify the individual elements of the list. When “C to D” is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),”etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5 % of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.” Furthermore, the expression “being the same” may mean “being substantially the same”. In other words, the expression “being the same” may include a range that can be tolerated by those of ordinary skill in the art. The other expressions may also be expressions from which “substantially”has been omitted.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

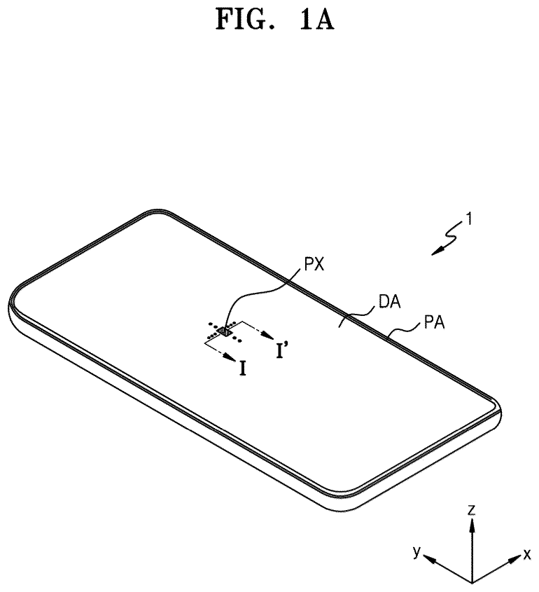

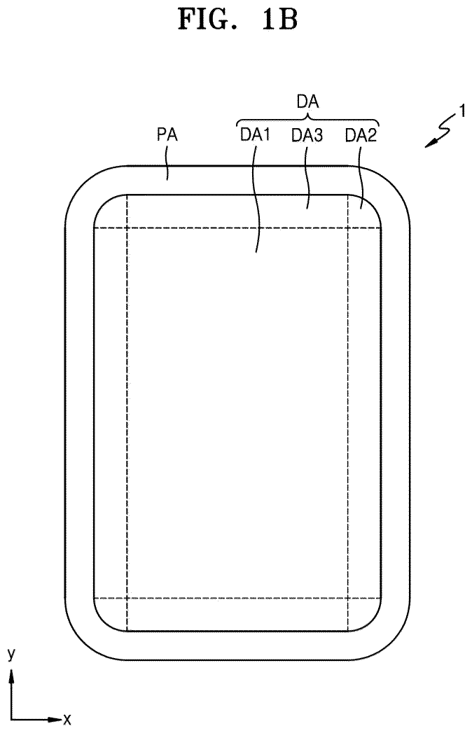

FIG. 1A is a schematic perspective view of a display device 1 according to one or more embodiments. FIG. 1B is a schematic plan view of the display device 1 according to one or more embodiments.

A display device according to one or more embodiments is a device that displays a moving image or a still image, and may be used as the display screen of not only portable electronic devices, such as a mobile phone, a smartphone, a tablet personal computer (PC), a mobile communication terminal, an electronic notebook, an e-book, a portable multimedia player (PMP), a navigation system, and an ultra-mobile PC (UMPC), but also various products, such as a television, a notebook computer, a monitor, a billboard, and the Internet of things (IoT). In addition, a display device according to one or more embodiments may be used in wearable devices, such as a smartwatch, a watch phone, a glasses-type display, and a head-mounted display (HMD). In addition, a display device according to one or more embodiments may be used as a car's instrument panel, a center information display (CID) placed on a car's center fascia or dashboard, a room mirror display replacing a car's side mirror, or a display placed on the back of a front seat as entertainment for a car's rear seat.

Referring to FIGS. 1A and 1B, the display device 1 may have an edge in a first direction and an edge in a second direction. In this regard, the first direction and the second direction may cross each other. For example, the first direction and the second direction may form an acute angle with respect to each other. As another example, the first direction and the second direction may form an obtuse angle with respect to each other or may be orthogonal to each other. Hereinafter, a case in which the first direction and the second direction are orthogonal to each other will be mainly described in detail. For example, the first direction may be a direction x or a direction −x, and the second direction may be a direction y or a direction −y. A third direction vertical to the first direction and the second direction may be a direction z or a direction −z.

The display device 1 may include a display area DA and a peripheral area PA outside the display area DA. The display device 1 may provide a certain image by using light emitted from a plurality of pixels PX arranged in the display area DA. The peripheral area PA, which is an area outside the display area DA, may be a non-display area in which pixels are not arranged. The display area DA may be entirely surrounded by the peripheral area PA (e.g., in plan view).

The display area DA may include a central portion DA1, a corner portion DA2, and a connection portion DA3. The corner portion DA2 of the display area DA may be an edge portion (e.g., a part of an edge portion) of the display area DA. The display area DA may include four corner portions DA2. The connection portion DA3 of the display area DA may be an area between corner portions DA2 of the display area DA. The corner portions DA2 may be arranged on both sides of the connection portion DA3 of the display area DA. The central portion DA1 of the display area DA may be arranged inside the corner portions DA2 and connection portions DA3 of the display area DA. In other words, the corner portions DA2 and the connection portions DA3 of the display area DA may surround the central portion DA1 of the display area DA (e.g., in plan view).

Although an organic light-emitting display device is described below as an example of a display device according to one or more embodiments, a display device described herein is not limited thereto. In one or more other embodiments, the display device described herein may be, for example, an inorganic light-emitting display (or an inorganic electroluminescent (EL) display) or a quantum dot light-emitting display. For example, an emission layer of a display element included in the display device may include an organic material or an inorganic material. Alternatively, the display device may include an emission layer, and quantum dots on a path of light emitted from the emission layer.

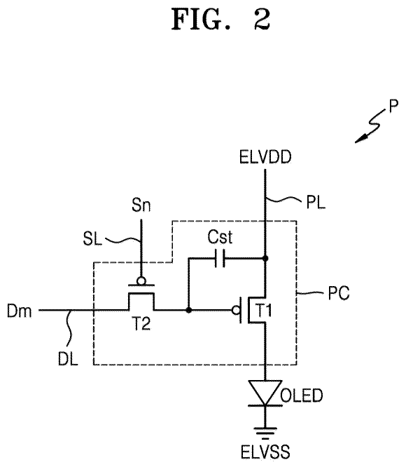

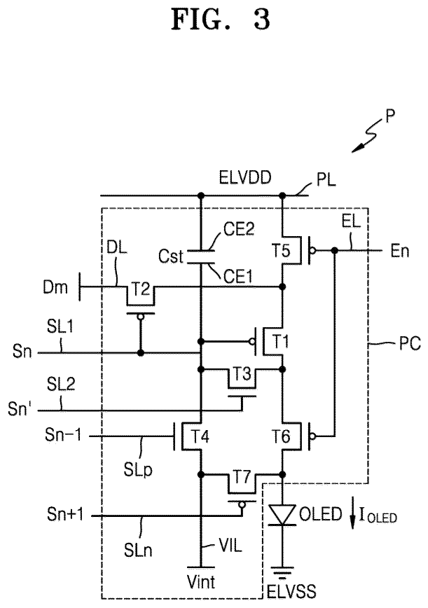

FIGS. 2 and 3 are equivalent circuit diagrams of a pixel P that may be included in a display device according to one or more embodiments.

Referring to FIG. 2, each pixel P may include a pixel circuit PC connected to a scan line SL and a data line DL and an organic light-emitting diode OLED connected to the pixel circuit PC.

The pixel circuit PC may include a driving thin-film transistor T1, a switching thin-film transistor T2, and a storage capacitor Cst. The switching thin-film transistor T2 may be connected to the scan line SL and the data line DL, and may be configured to transmit a data signal Dm input through the data line DL to the driving thin-film transistor T1 according to a scan signal Sn input through the scan line SL.

The storage capacitor Cst may be connected to the switching thin-film transistor T2 and a driving voltage line PL, and may store a voltage corresponding to a difference between a voltage received from the switching thin-film transistor T2 and a driving voltage ELVDD supplied to the driving voltage line PL.

The driving thin-film transistor T1 may be connected to the driving voltage line PL and the storage capacitor Cst, and may be configured to control a driving current flowing through the organic light-emitting diode OLED from the driving voltage line PL, in response to a voltage value stored in the storage capacitor Cst. The organic light-emitting diode OLED may emit light having a certain luminance according to the driving current.

Although FIG. 2 shows a case in which the pixel circuit PC includes two thin-film transistors and one storage capacitor, one or more embodiments are not limited thereto. For example, the pixel circuit PC may include three or more thin-film transistors and/or two or more storage capacitors. In one or more embodiments, the pixel circuit PC may include seven thin-film transistors and one storage capacitor. Alternatively, the pixel circuit PC may include seven thin-film transistors and two storage capacitors.

Referring to FIG. 3, one pixel P may include the pixel circuit PC, and the organic light-emitting diode OLED electrically connected to the pixel circuit PC.

In one or more embodiments, as shown in FIG. 3, the pixel circuit PC may include a plurality of thin-film transistors T1 to T7 and the storage capacitor Cst. The thin-film transistors T1 to T7 and the storage capacitor Cst may be connected to signal lines SL1, SL2, SLp, SLn, EL, and DL, an initialization voltage line VIL, and the driving voltage line PL. In one or more embodiments, at least one of the signal lines SL1, SL2, SLp, SLn, EL, or DL, for example, the initialization voltage line VIL and/or the driving voltage line PL, may be shared by neighboring pixels P.

The thin-film transistors T1 to T7 may include the driving thin-film transistor T1, the switching thin-film transistor T2, a compensation thin-film transistor T3, a first initialization thin-film transistor T4, an operation control thin-film transistor T5, an emission control thin-film transistor T6, and a second initialization thin-film transistor T7.

One or more of the plurality of thin-film transistors T1 to T7 may be provided as n-channel MOSFETs (NMOS), and one or more others may be provided as p-channel MOSFETs (PMOS).

For example, as in FIG. 3, the compensation thin-film transistor T3 and the first initialization thin-film transistor T4 among the plurality of thin-film transistors T1 to T7 may be provided as n-channel MOSFETs (NMOS), and the other thin-film transistors may be provided as p-channel MOSFETs (PMOS).

In one or more embodiments, the compensation thin-film transistor T3, the first initialization thin-film transistor T4, and the second initialization thin-film transistor T7 among the plurality of thin-film transistors T1 to T7 may be provided as n-channel MOSFETs (NMOS), and the other thin-film transistors may be provided as p-channel MOSFETs (PMOS). Alternatively, only one of the plurality of thin-film transistors T1 to T7 may be provided as NMOS, and the other thin-film transistors may be provided as PMOS. Alternatively, all of the plurality of thin-film transistors T1 to T7 may be NMOS.

The signal lines may include a first scan line SL1 configured to transmit a first scan signal Sn, a second scan line SL2 configured to transmit a second scan signal Sn′, a previous scan line SLp configured to transmit a previous scan signal Sn−1 to the first initialization thin-film transistor T4, an emission control line EL configured to transmit an emission control signal En to the operation control thin-film transistor T5 and the emission control thin-film transistor T6, a next scan line SLn configured to transmit a next scan signal Sn+1 to the second initialization thin-film transistor T7, and the data line DL crossing the first scan line SL1 and configured to transmit the data signal Dm.

The driving voltage line PL may be configured to transfer the driving voltage ELVDD to the driving thin-film transistor T1, and the initialization voltage line VIL may be configured to transfer an initialization voltage Vint for initializing the driving thin-film transistor T1 and a pixel electrode.

A driving gate electrode of the driving thin-film transistor T1 is connected to the storage capacitor Cst, a driving source region of the driving thin-film transistor T1 is connected to the driving voltage line PL via the operation control thin-film transistor T5, and a driving drain region of the driving thin-film transistor T1 is electrically connected to a pixel electrode of the organic light-emitting diode OLED via the emission control thin-film transistor T6. The driving thin-film transistor T1 may be configured to receive the data signal Dm according to a switching operation of the switching thin-film transistor T2, and may supply a driving current I_{OLED} to the organic light-emitting diode OLED.

A switching gate electrode of the switching thin-film transistor T2 is connected to the first scan line SL1, a switching source region of the switching thin-film transistor T2 is connected to the data line DL, and a switching drain region of the switching thin-film transistor T2 is connected to the driving source region of the driving thin-film transistor T1, and is also connected to the driving voltage line PL via the operation control thin-film transistor T5. The switching thin-film transistor T2 may be turned on according to the first scan signal Sn received through the first scan line SL1, and may be configured to perform a switching operation for transferring the data signal Dm transmitted through the data line DL to the driving source region of the driving thin-film transistor T1.

A compensation gate electrode of the compensation thin-film transistor T3 is connected to the second scan line SL2. A compensation drain region of the compensation thin-film transistor T3 is connected to the driving drain region of the driving thin-film transistor T1, and is also connected to the pixel electrode of the organic light-emitting diode OLED via the emission control thin-film transistor T6. A compensation source region of the compensation thin-film transistor T3 is connected to a bottom electrode CE1 of the storage capacitor Cst and the driving gate electrode of the driving thin-film transistor T1. In addition, the compensation source region is connected to a first initialization drain region of the first initialization thin-film transistor T4.

The compensation thin-film transistor T3 is turned on according to the second scan signal Sn′ received through the second scan line SL2, and is configured to diode-connect the driving thin-film transistor T1 by electrically connecting the driving gate electrode and the driving drain region of the driving thin-film transistor T1 to each other.

A first initialization gate electrode of the first initialization thin-film transistor T4 is connected to the previous scan line SLp. A first initialization source region of the first initialization thin-film transistor T4 is connected to a second initialization source region of the second initialization thin-film transistor T7 and the initialization voltage line VIL. The first initialization drain region of the first initialization thin-film transistor T4 is connected to the bottom electrode CE1 of the storage capacitor Cst, the compensation source region of the compensation thin-film transistor T3, and the driving gate electrode of the driving thin-film transistor T1. The first initialization thin-film transistor T4 may be turned on according to the previous scan signal Sn−1 received through the previous scan line SLp, and may be configured to perform an initialization operation for initializing a voltage of the driving gate electrode of the driving thin-film transistor T1 by transferring the initialization voltage Vint to the driving gate electrode of the driving thin-film transistor T1.

An operation control gate electrode of the operation control thin-film transistor T5 is connected to the emission control line EL, an operation control source region of the operation control thin-film transistor T5 is connected to the driving voltage line PL, and an operation control drain region of the operation control thin-film transistor T5 is connected to the driving source region of the driving thin-film transistor T1 and the switching drain region of the switching thin-film transistor T2.

An emission control gate electrode of the emission control thin-film transistor T6 is connected to the emission control line EL, an emission control source region of the emission control thin-film transistor T6 is connected to the driving drain region of the driving thin-film transistor T1 and the compensation drain region of the compensation thin-film transistor T3, and an emission control drain region of the emission control thin-film transistor T6 is electrically connected to a second initialization drain region of the second initialization thin-film transistor T7 and the pixel electrode of the organic light-emitting diode OLED.

As the operation control thin-film transistor T5 and the emission control thin-film transistor T6 are concurrently or substantially simultaneously turned on according to the emission control signal En received through the emission control line EL, the driving voltage ELVDD is transferred to the organic light-emitting diode OLED, and thus, the driving current I_{OLED} flows through the organic light-emitting diode OLED.

A second initialization gate electrode of the second initialization thin-film transistor T7 is connected to the next scan line SLn, the second initialization drain region of the second initialization thin-film transistor T7 is connected to the emission control drain region of the emission control thin-film transistor T6 and the pixel electrode of the organic light-emitting diode OLED, and the second initialization source region of the second initialization thin-film transistor T7 is connected to the first initialization source region of the first initialization thin-film transistor T4 and the initialization voltage line VIL. The second initialization thin-film transistor T7 is turned on according to the next scan signal Sn+1 received through the next scan line SLn and is configured to initialize the pixel electrode of the organic light-emitting diode OLED.

As shown in FIG. 3, the second initialization thin-film transistor T7 may be connected to the next scan line SLn. In one or more embodiments, the second initialization thin-film transistor T7 may be connected to the emission control line EL, and may be driven according to the emission control signal En. Positions of the source and drain regions may be reversed depending on the type (p-type or n-type) of a transistor.

The storage capacitor Cst may include the bottom electrode CE1 and a top electrode CE2. The bottom electrode CE1 of the storage capacitor Cst is connected to the driving gate electrode of the driving thin-film transistor T1, and the top electrode CE2 of the storage capacitor Cst is connected to the driving voltage line PL. The storage capacitor Cst may store a charge corresponding to a difference between a driving gate electrode voltage of the driving thin-film transistor T1 and the driving voltage ELVDD.

Detailed operations of each pixel P according to one or more embodiments are as follows.

During an initialization period, when the previous scan signal Sn−1 is supplied through the previous scan line SLp, the first initialization thin-film transistor T4 is turned on in response to the previous scan signal Sn−1, and the driving thin-film transistor T1 is initialized by the initialization voltage Vint supplied from the initialization voltage line VIL.

During a data programming period, when the first scan signal Sn and the second scan signal Sn′ are supplied through the first scan line SL1 and the second scan line SL2, the switching thin-film transistor T2 and the compensation thin-film transistor T3 are turned on in response to the first scan signal Sn and the second scan signal Sn′. In this regard, the driving thin-film transistor T1 is diode-connected by the turned-on compensation thin-film transistor T3 and is forward biased.

Then, a compensation voltage Dm+Vth (where Vth is a (−) value) reduced from the data signal Dm supplied from the data line DL by the threshold voltage Vth of the driving thin-film transistor T1 is applied to the driving gate electrode of the driving thin-film transistor T1.

The driving voltage ELVDD and the compensation voltage Dm+Vth are applied to two ends of the storage capacitor Cst, and a charge corresponding to a voltage difference between the two ends is stored in the storage capacitor Cst.

During an emission period, the operation control thin-film transistor T5 and the emission control thin-film transistor T6 are turned on by the emission control signal En supplied from the emission control line EL. The driving current I_{OLED} according to a voltage difference between a voltage of the driving gate electrode of the driving thin-film transistor T1 and the driving voltage ELVDD occurs, and the driving current I_{OLED} is supplied to the organic light-emitting diode OLED through the emission control thin-film transistor T6.

In one or more embodiments, at least one of the plurality of thin-film transistors T1 to T7 may include a semiconductor layer including an oxide semiconductor, and the others may include a semiconductor layer including a silicon semiconductor.

For example, the driving thin-film transistor T1, which directly affects the brightness of a display device, may include a semiconductor layer formed of polycrystalline silicon with high reliability, through which a high-resolution display device may be implemented.

Meanwhile, an oxide semiconductor has relatively high carrier mobility and relatively low leakage current, and accordingly, a voltage drop is not significant even when a driving time is long. That is, a change in the color of an image due to a voltage drop is not significant even during low-frequency driving, which makes low-frequency driving possible.

As described above, because an oxide semiconductor has low leakage current, at least one of the compensation thin-film transistor T3, the first initialization thin-film transistor T4, or the second initialization thin-film transistor T7, which are connected to the driving gate electrode of the driving thin-film transistor T1, may include an oxide semiconductor, and thus, a leakage current that may flow to the driving gate electrode may be reduced or prevented and power consumption may also be reduced.

In one or more embodiments, the driving thin-film transistor T1, the switching thin-film transistor T2, the operation control thin-film transistor T5, the emission control thin-film transistor T6, and the second initialization thin-film transistor T7 may include a semiconductor layer including a silicon semiconductor, and the compensation thin-film transistor T3 and the first initialization thin-film transistor T4 may include a semiconductor layer including an oxide semiconductor. However, one or more embodiments are not limited thereto.

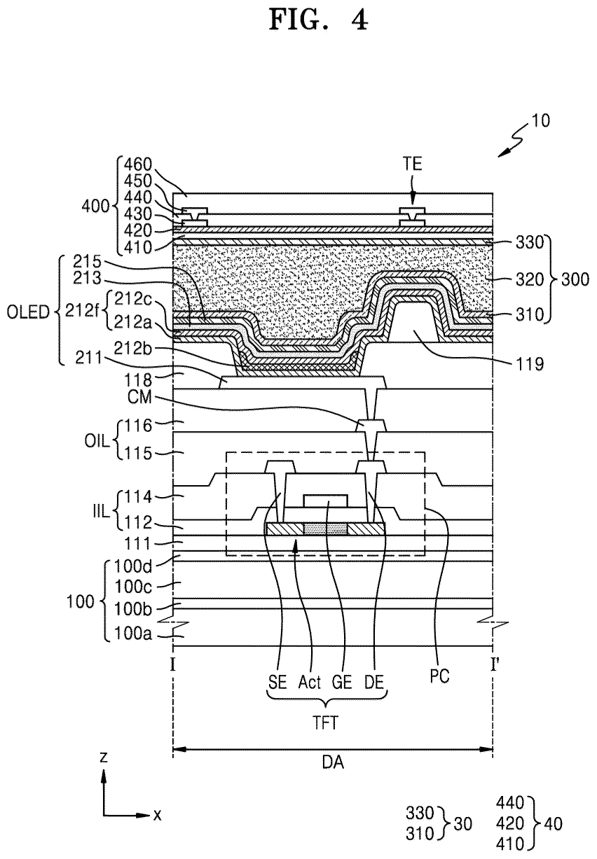

FIG. 4 is a schematic cross-sectional view of a display device. For example, FIG. 4 is a schematic cross-sectional view of the display device 1 of FIG. 1A, taken along the line I-I′ of FIG. 1A.

Referring to FIG. 4, a display panel 10 may include a substrate 100, an inorganic insulating layer IIL, an organic insulating layer OIL, the pixel circuit PC, a connection electrode CM, the organic light-emitting diode OLED, a third organic insulating layer 118, a spacer 119, and an encapsulation layer 300. That is, the substrate 100, the inorganic insulating layer IIL, the organic insulating layer OIL, the pixel circuit PC, the connection electrode CM, the organic light-emitting diode OLED, the third organic insulating layer 118, the spacer 119, and the encapsulation layer 300 may be arranged in the display area DA of the display panel 10. The organic light-emitting diode OLED is a type of a display element and is described as an example.

The substrate 100 may include a first base layer 100a, a first barrier layer 100b, a second base layer 100c, and a second barrier layer 100d. In one or more embodiments, the first base layer 100a, the first barrier layer 100b, the second base layer 100c, and the second barrier layer 100d may be sequentially stacked in a thickness direction of the substrate 100.

At least one of the first base layer 100a or the second base layer 100c may include polymer resin, such as polyethersulfone, polyarylate, polyetherimide, polyethylene naphthalate, polyethylene terephthalate, polyphenylene sulfide, polyimide, polycarbonate, cellulose triacetate, or cellulose acetate propionate.

The first barrier layer 100b and the second barrier layer 100d are barrier layers that reduce or prevent intrusion of external foreign substances, and may each have a single-layer or multi-layer structure including an inorganic material, such as silicon nitride (SiNX), silicon oxide (SiO2) and/or silicon oxynitride (SiON).

A buffer layer 111 may be arranged on the substrate 100 (as used herein, “arranged on” may mean “above”). The buffer layer 111 may include an inorganic insulating material, such as silicon nitride (SiNX), silicon oxynitride (SiON) and silicon oxide (SiO2), and may have a single-layer or multi-layer structure including the above-described inorganic insulating material.

The inorganic insulating layer IIL may be arranged on the buffer layer 111. The inorganic insulating layer IIL may include a first inorganic insulating layer 112 and a second inorganic insulating layer 114. However, one or more embodiments are not limited thereto.

The pixel circuit PC may be arranged in the display area DA. The pixel circuit PC may include a thin-film transistor TFT. The thin-film transistor TFT may include a semiconductor layer Act, a gate electrode GE, a source electrode SE, and a drain electrode DE.

The semiconductor layer Act may be arranged on the buffer layer 111. The semiconductor layer Act may include polysilicon. Alternatively, the semiconductor layer Act may include amorphous silicon, an oxide semiconductor, or an organic semiconductor. The semiconductor layer Act may include a channel region, and a drain region and a source region respectively arranged on sides of the channel region.

The gate electrode GE may be arranged over the semiconductor layer Act. The gate electrode GE may overlap the channel region. The gate electrode GE may include a low-resistance metal material. The gate electrode GE may include a conductive material including molybdenum (Mo), aluminum (Al), copper (Cu), titanium (Ti), etc., and may have a multi-layer or single-layer structure including the above-described material.

The first inorganic insulating layer 112 may be arranged between the semiconductor layer Act and the gate electrode GE. The first inorganic insulating layer 112 may include an inorganic insulating material, such as silicon oxide (SiO2), silicon nitride (SiNX), silicon oxynitride (SiON), aluminum oxide (Al2O3), titanium oxide (TiO2), tantalum oxide (Ta2O5), hafnium oxide (HfO2), or zinc oxide (ZnO).

The second inorganic insulating layer 114 may be arranged on the gate electrode GE. The second inorganic insulating layer 114 may cover the gate electrode GE. The second inorganic insulating layer 114 may include an inorganic insulating material, such as silicon oxide (SiO2), silicon nitride (SiNX), silicon oxynitride (SiON), aluminum oxide (Al2O3), titanium oxide (TiO2), tantalum oxide (Ta2O5), hafnium oxide (HfO2), or zinc oxide (ZnO).

Each of the drain electrode DE and the source electrode SE may be on the second inorganic insulating layer 114. Each of the drain electrode DE and the source electrode SE may be connected to the semiconductor layer Act through a contact hole defined in the first inorganic insulating layer 112 and the second inorganic insulating layer 114. The drain electrode DE and the source electrode SE may include a highly conductive material. The drain electrode DE and the source electrode SE may include a conductive material including molybdenum (Mo), aluminum (Al), copper (Cu), titanium (Ti), etc., and may have a multi-layer or single-layer structure including the above-described material. For example, the drain electrode DE and the source electrode SE may have a multi-layer structure of titanium (Ti)/aluminum (Al)/titanium (Ti).

The organic insulating layer OIL may be arranged on the inorganic insulating layer IIL. The organic insulating layer OIL may include a first organic insulating layer 115 and a second organic insulating layer 116. Although FIG. 4 shows the organic insulating layer OIL including two layers, one or more embodiments are not limited thereto. The organic insulating layer OIL may include three or four layers.

The first organic insulating layer 115 may cover the drain electrode DE and the source electrode SE. The first organic insulating layer 115 may include an organic insulating material, such as a general commercial polymer, such as polymethylmethacrylate (PMMA) or polystyrene (PS), a polymer derivative having a phenol-based group, an acryl-based polymer, an imide-based polymer, an aryl ether-based polymer, an amide-based polymer, a fluorine-based polymer, a p-xylene-based polymer, a vinyl alcohol-based polymer, or a blend thereof.

The connection electrode CM may be arranged on the first organic insulating layer 115. In this regard, the connection electrode CM may be connected to the drain electrode DE or to the source electrode SE through a contact hole in the first organic insulating layer 115. The connection electrode CM may include a highly conductive material. The connection electrode CM may include a conductive material including molybdenum (Mo), aluminum (Al), copper (Cu), titanium (Ti), etc., and may have a multi-layer or single-layer structure including the above-described material. For example, the connection electrode CM may have a multi-layer structure of titanium (Ti)/aluminum (Al)/titanium (Ti).

The second organic insulating layer 116 may be arranged on the connection electrode CM. The second organic insulating layer 116 may cover the connection electrode CM. The second organic insulating layer 116 may include a material that is the same as, or different from, that of the first organic insulating layer 115.

A light-emitting diode may be arranged on the second organic insulating layer 116. For example, the organic light-emitting diode OLED may be arranged on the second organic insulating layer 116. Alternatively, in one or more embodiments, an inorganic light-emitting diode, etc., may be arranged on the second organic insulating layer 116.

The organic light-emitting diode OLED may emit red, green, or blue light, or may emit red, green, blue, or white light. The organic light-emitting diode OLED may include a first electrode 211, an emission layer 212b, a functional layer 212f, a second electrode 213, and a capping layer 215. The first electrode 211 may be a pixel electrode (e.g., an anode) of the organic light-emitting diode OLED, and the second electrode 213 may be an opposite electrode (e.g., a cathode) of the organic light-emitting diode OLED.

The first electrode 211 may be arranged on the second organic insulating layer 116. The first electrode 211 may be electrically connected to the connection electrode CM through a contact hole defined in the second organic insulating layer 116. The first electrode 211 may include conductive oxide, such as indium tin oxide (ITO), indium zinc oxide (IZO), zinc oxide (ZnO), indium oxide (In2O3), indium gallium oxide (IGO), or aluminum zinc oxide (AZO). In one or more embodiments, the first electrode 211 may include a reflection layer including silver (Ag), magnesium (Mg), aluminum (Al), platinum (Pt), palladium (Pd), gold (Au), nickel (Ni), neodymium (Nd), iridium (Ir), chromium (Cr), or a compound thereof. In one or more embodiments, the first electrode 211 may further include a layer on/under the above-described reflection layer and formed of ITO, IZO, ZnO, or In2O3. For example, the first electrode 211 may have a multi-layer structure of ITO/Ag/ITO.

The third organic insulating layer 118, in which an opening exposing at least a portion of the first electrode 211 is defined, may be arranged on the first electrode 211. An emission area of light emitted from the organic light-emitting diode OLED may be defined by the opening defined in the third organic insulating layer 118. For example, a width of the opening may correspond to a width of the emission area.

The third organic insulating layer 118 may include an organic insulating material. Alternatively, the third organic insulating layer 118 may include an inorganic insulating material, such as silicon nitride, silicon oxynitride, or silicon oxide.

Alternatively, the third organic insulating layer 118 may include an organic insulating material and an inorganic insulating material. In one or more embodiments, the third organic insulating layer 118 may include a light-blocking material. The light-blocking material may include carbon black, carbon nanotubes, resin or paste including black dye, metal particles, for example, nickel, aluminum, molybdenum, and alloys thereof, metal oxide particles (e.g., chromium oxide), or metal nitride particles (e.g., chromium nitride). When the third organic insulating layer 118 includes a light-blocking material, the reflection of external light caused by metal structures arranged below the third organic insulating layer 118 may be reduced.

The spacer 119 may be arranged on the third organic insulating layer 118. The spacer 119 may include an organic insulating material, such as polyimide. Alternatively, the spacer 119 may include an inorganic insulating material, such as silicon nitride (SiNX) or silicon oxide (SiO2), or may include an organic insulating material and an inorganic insulating material.

In one or more embodiments, the spacer 119 may include the same material as that of the third organic insulating layer 118. In this case, the third organic insulating layer 118 and the spacer 119 may be formed together during a mask process using a halftone mask or the like. Alternatively, the spacer 119 and the third organic insulating layer 118 may include different materials, respectively.

The emission layer 212b may be arranged in the opening of the third organic insulating layer 118. The emission layer 212b may include a high-molecular weight or low-molecular weight organic material for emitting light of a certain color.

The functional layer 212f may include a first functional layer 212a and a second functional layer 212c. The first functional layer 212a may be arranged between the first electrode 211 and the emission layer 212b, and the second functional layer 212c may be arranged between the emission layer 212b and the second electrode 213. However, at least one of the first functional layer 212a or the second functional layer 212c may be omitted. Hereinafter, a case where each of the first functional layer 212a and the second functional layer 212c is arranged will be mainly described.

The first functional layer 212a may include a hole transport layer (HTL) and/or a hole injection layer (HIL). The second functional layer 212c may include an electron transport layer (ETL) and/or an electron injection layer (EIL). The first functional layer 212a and/or the second functional layer 212c may be common layers that entirely cover the substrate 100 as the second electrode 213 described below does.

The second electrode 213 may be arranged on the functional layer 212f. The second electrode 213 may include a conductive material having a low work function. For example, the second electrode 213 may include a (semi)transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or an alloy thereof. Alternatively, the second electrode 213 may further include a layer, such as ITO, IZO, ZnO, or In2O3, on a (semi)transparent layer including the above-described material.

In one or more embodiments, the capping layer 215 may be arranged on the second electrode 213. The capping layer 215 may include lithium fluoride (LiF), an inorganic material and/or an organic material.

The encapsulation layer 300 may be arranged on the organic light-emitting diode OLED. The encapsulation layer 300 may cover the organic light-emitting diode OLED. The encapsulation layer 300 may be arranged on the second electrode 213 and/or the capping layer 215. In one or more embodiments, the encapsulation layer 300 may include at least one inorganic encapsulation layer 30 and at least one organic encapsulation layer. FIG. 4 shows the encapsulation layer 300 including a first inorganic encapsulation layer 310, an organic encapsulation layer 320, and a second inorganic encapsulation layer 330, which are sequentially stacked on one another.

The inorganic encapsulation layer 30 may include the first inorganic encapsulation layer 310 and the second inorganic encapsulation layer 330. The first inorganic encapsulation layer 310 and the second inorganic encapsulation layer 330 may include one or more inorganic materials among aluminum oxide, titanium oxide, tantalum oxide, hafnium oxide, zinc oxide, silicon oxide, silicon nitride, or silicon oxynitride. The first inorganic encapsulation layer 310 and the second inorganic encapsulation layer 330 may have a single-layer or multi-layer structure including the above-described material. The organic encapsulation layer 320 may include a polymer-based material. Examples of the polymer-based material may include acryl-based resin, epoxy-based resin, polyimide, and polyethylene. In one or more embodiments, the organic encapsulation layer 320 may include acrylate.

An input-sensing layer 400 may be arranged on the encapsulation layer 300. The input-sensing layer 400 may include a first touch-insulating layer 410, a second touch-insulating layer 420, a first conductive layer 430, a third touch-insulating layer 440, a second conductive layer 450, and a planarization layer 460. A touch-insulating layer 40 may include the first touch-insulating layer 410, the second touch-insulating layer 420, and/or the third touch-insulating layer 440.

In one or more embodiments, the first touch-insulating layer 410 may be arranged on the second inorganic encapsulation layer 330, and the second touch-insulating layer 420 may be arranged on the first touch-insulating layer 410. In one or more embodiments, the first touch-insulating layer 410 and the second touch-insulating layer 420 may include an organic insulating material.

In one or more embodiments, at least one of the first touch-insulating layer 410 or the second touch-insulating layer 420 may be omitted. For example, in one or more embodiments, the first touch-insulating layer 410 may be omitted, and the second touch-insulating layer 420 may be arranged on the second inorganic encapsulation layer 330, and the first conductive layer 430 may be arranged on the second touch-insulating layer 420.

The first conductive layer 430 may be arranged on the second touch-insulating layer 420, and the third touch-insulating layer 440 may be arranged on the first conductive layer 430. In one or more embodiments, the third touch-insulating layer 440 may include an organic insulating material.

The second conductive layer 450 may be arranged on the third touch-insulating layer 440. A touch electrode TE of the input-sensing layer 400 may have a structure in which the first conductive layer 430 and the second conductive layer 450 are connected to each other. Alternatively, the touch electrode TE may be formed in one of the first conductive layer 430 and the second conductive layer 450, and may include a metal line included in the corresponding conductive layer. Each of the first conductive layer 430 and the second conductive layer 450 may include at least one of aluminum (Al), copper (Cu), titanium (Ti), molybdenum (Mo), or indium tin oxide (ITO), and may have a single-layer or multi-layer structure including the above-described material. For example, each of the first conductive layer 430 and the second conductive layer 450 may have a three-layer structure of a titanium layer/an aluminum layer/a titanium layer.

In one or more embodiments, the planarization layer 460 may cover the second conductive layer 450. The planarization layer 460 may include an organic insulating material.

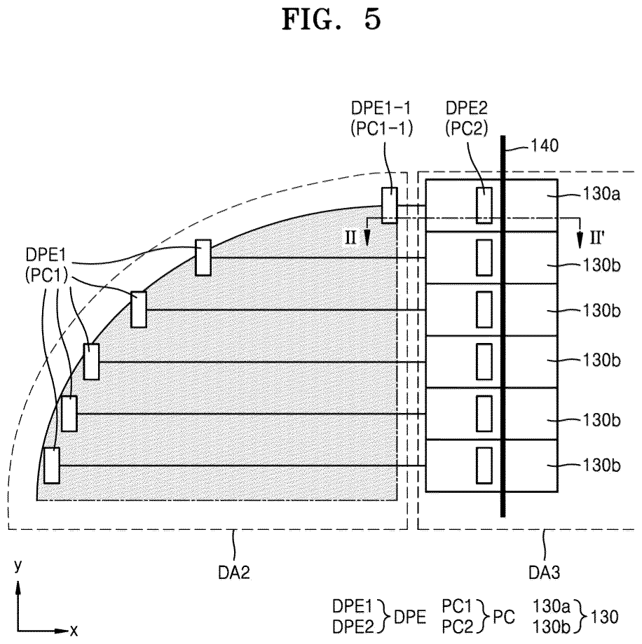

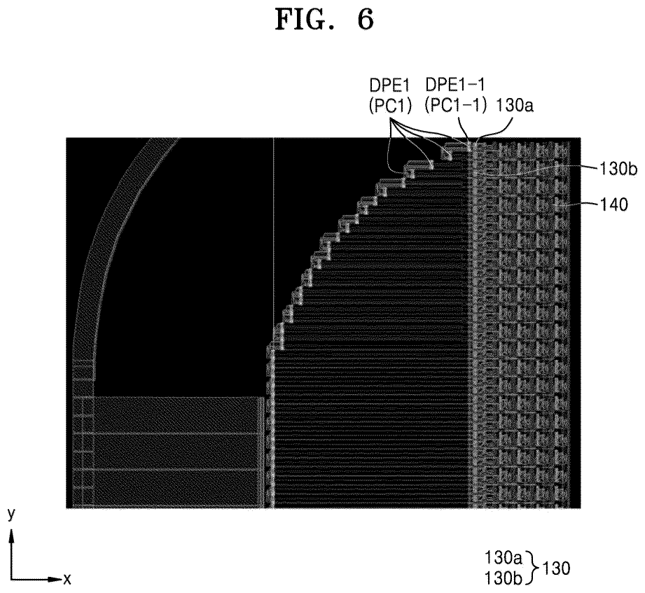

FIG. 5 schematically shows an enlarged plan view of a portion of a display area of a display device. FIG. 6 schematically shows a portion of a display area of a display device.

Referring to FIGS. 5 and 6, a first display element DPE1 may be arranged in the corner portion DA2 of the display area DA. A first pixel circuit unit PC1 electrically connected to the first display element DPE1 may be arranged in the corner portion DA2 of the display area DA to correspond to the first display element DPE1. A second display element DPE2 may be arranged in the connection portion DA3 of the display area DA. A second pixel circuit unit PC2 electrically connected to the second display element DPE2 may be arranged in the connection portion DA3 of the display area DA to correspond to the second display element DPE2. In the drawing, for convenience, the display element DPE1 and DPE2, and the pixel circuit unit PC1 and PC2 corresponding thereto, are denoted by one quadrangular figure.

A gate driver 130a or 130b may be arranged in the connection portion DA3 of the display area DA. The gate driver 130a or 130b may overlap the second display element DPE2 arranged in the connection portion DA3 of the display area DA, and at least a portion of the second pixel circuit unit PC2 arranged in correspondence with the second display element DPE2. The gate driver 130a or 130b may be electrically connected to the first pixel circuit unit PC1 arranged in the corner portion DA2 of the display area DA. In addition, the gate driver 130a or 130b may be electrically connected to the second pixel circuit unit PC2 arranged in the connection portion DA3 of the display area DA.

The gate driver 130a or 130b may be provided in a plurality of numbers. A plurality of gate drivers 130 may be arranged in a line in a second direction (e.g., a direction y or a direction-y). The first display element DPE1 may be provided in a plurality of numbers. A plurality of first display elements DPE1 may include a 1st-1 display element DPE1-1 arranged at an uppermost part of the corner portion DA2 of the display area DA. The first pixel circuit unit PC1 may be provided in a plurality of numbers. A plurality of first pixel circuit units PC1 may include a 1st-1 pixel circuit unit PC1-1 arranged at the uppermost part of the corner portion DA2 of the display area DA. The 1st-1 pixel circuit unit PC1-1 may be electrically connected to the 1st-1 display element DPE1-1. The plurality of gate drivers 130 may include a first gate driver 130a electrically connected to the 1st-1 pixel circuit unit PC1-1. The first gate driver 130a may be arranged at an uppermost part of the connection portion DA3 of the display area DA, and may be closest to the 1st-1 pixel circuit unit PC1-1. The plurality of gate drivers 130 may be arranged in a line in the second direction (e.g., the direction y or the direction-y) with respect to the first gate driver 130a.

The first pixel circuit unit PC1 corresponding to the first display element DPE1 arranged in the corner portion DA2 of the display area DA, and electrically connected to the first display element DPE1 may be electrically connected to the gate driver 130a or 130b apart therefrom in a first direction (e.g., a direction x). For example, the first pixel circuit unit PC1 may be electrically connected to the gate driver 130a or 130b that is closest of the plurality of gate drivers 130 apart therefrom in the first direction (e.g., the direction x). For example, the 1st-1 pixel circuit unit PC1-1 corresponding to the 1st-1 display element DPE1-1 may be electrically connected to the first gate driver 130a that is closest of the plurality of gate drivers 130 apart therefrom in the first direction (e.g., the direction x).

A clock line 140 may be arranged in the connection portion DA3 of the display area DA to overlap the plurality of gate drivers 130. The clock line 140 may extend in the second direction (e.g., the direction y or the direction-y) to overlap the plurality of gate drivers 130. In other words, the clock line 140 may extend in the direction in which the plurality of gate drivers 130 are arranged in a line. In addition, the clock line 140 may be configured to electrically connect the plurality of gate drivers 130 to each other.

When the plurality of gate drivers 130 electrically connected to the plurality of first pixel circuit units PC1 corresponding to the plurality of first display elements DPE1 arranged in the corner portion DA2 of the display area DA are arranged in the corner portion DA2 of the display area DA, according to the curvature of the corner portion DA2 of the display area DA, circuits of the gate drivers 130 overlap each other, or there might be no room for the clock line 140 configured to connect the gate drivers 130 to each other.

In one or more embodiments, the plurality of gate drivers 130, which are electrically connected to the plurality of first pixel circuit units PC1 that correspond to the plurality of first display elements DPE1 arranged in the corner portion DA2 of the display area DA, may be arranged in a line in the connection portion DA3 of the display area DA, and thus, the plurality of gate drivers 130, which are configured to provide a signal to the plurality of first pixel circuit units PC1 corresponding to the first display elements DPE1 arranged in the corner portion DA2 of the display area DA, may be arranged in the display area DA as a panel embedded type, and accordingly, an area for an image to be displayed on a display device may be enlarged to improve the quality and reliability of a display device.

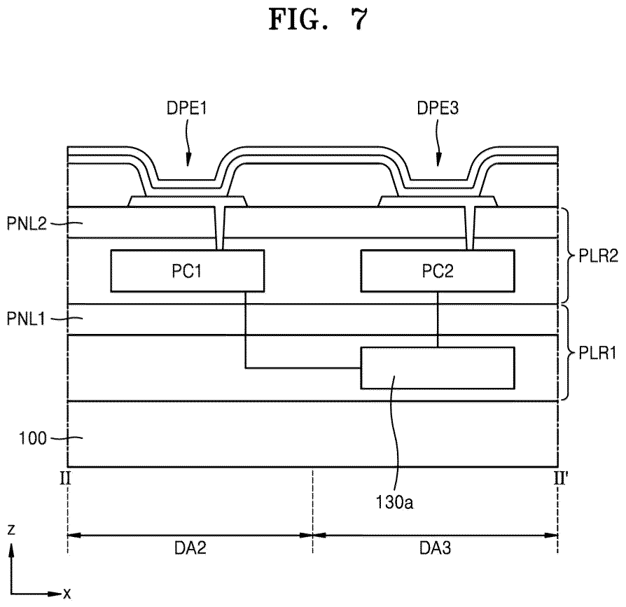

FIG. 7 is a schematic cross-sectional view of the display area of the display device of FIG. 5, taken along the line II-II′ of FIG. 5.

In one or more embodiments, a first layer PLR1 may be a layer including the first gate driver 130a. A second layer PLR2 may include the display elements DPE1 and DPE2, and the pixel circuit units PC1 and PC2 corresponding thereto. The second layer PLR2 may be arranged on the first layer PLR1. In other words, the first pixel circuit unit PC1 and the second pixel circuit unit PC2 may be arranged above the first gate driver 130a. The second layer PLR2 may be arranged on the first layer PLR1, so that the plurality of gate drivers 130 (refer to FIG. 5), in addition to the first gate drivers 130a, may be arranged in the display area DA rather than the peripheral area PA (refer to FIG. 1A), and thus, an area for an image to be displayed on a display device may be enlarged.

The second display element DPE2 and the second pixel circuit unit PC2 corresponding thereto may be arranged above the first gate driver 130a arranged in the connection portion DA3 of the display area DA to overlap the first gate driver 130a. However, one or more embodiments are not limited thereto.

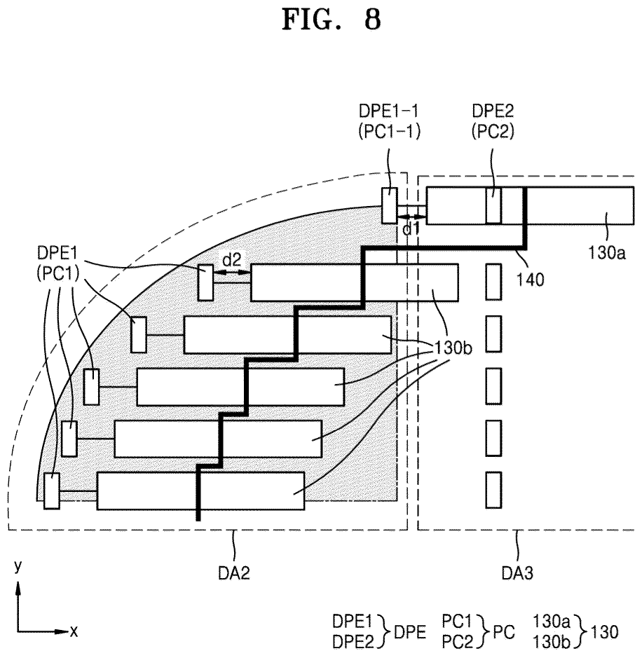

FIG. 8 schematically shows an enlarged plan view of a portion of a display area of a display device.

Referring to FIG. 8, the first display element DPE1 may be arranged in the corner portion DA2 of the display area DA. The first pixel circuit unit PC1 electrically connected to the first display element DPE1 may be arranged in the corner portion DA2 of the display area DA to correspond to the first display element DPE1. The second display element DPE2 may be arranged in the connection portion DA3 of the display area DA. The second pixel circuit unit PC2 electrically connected to the second display element DPE2 may be arranged in the connection portion DA3 of the display area DA to correspond to the second display element DPE2.

The gate driver 130a or 130b may be arranged in the connection portion DA3 of the display area DA. The gate driver 130a or 130b may overlap the second display element DPE2 arranged in the connection portion DA3 of the display area DA, and may overlap at least a portion of the second pixel circuit unit PC2 arranged in correspondence with the second display element DPE2. The gate driver 130a or 130b may be electrically connected to the first pixel circuit unit PC1 arranged in the corner portion DA2 of the display area DA. In addition, the gate driver 130a or 130b may be electrically connected to the second pixel circuit unit PC2 arranged in the connection portion DA3 of the display area DA.

The gate driver 130a or 130b may be provided in a plurality of numbers. The plurality of gate drivers 130 may be arranged in a second direction (e.g., a direction y or a direction-y), and may be arranged in steps, or may be respectively offset, in a direction from the connection portion DA3 of the display area DA toward the corner portion DA2. The first display element DPE1 may be provided in a plurality of numbers. The plurality of first display elements DPE1 may include the 1st-1 display element DPE1-1 arranged at an uppermost part of the corner portion DA2 of the display area DA. The first pixel circuit unit PC1 may be provided in a plurality of numbers. The plurality of first pixel circuit units PC1 may include the 1st-1 pixel circuit unit PC1-1 arranged at the uppermost part of the corner portion DA2 of the display area DA. The 1st-1 pixel circuit unit PC1-1 may be electrically connected to the 1st-1 display element DPE1-1. The plurality of gate drivers 130 may include the first gate driver 130a electrically connected to the 1st-1 pixel circuit unit PC1-1. The first gate driver 130a may be arranged at an uppermost part of the connection portion DA3 of the display area DA, and may be closest to the 1st-1 pixel circuit unit PC1-1. The plurality of gate drivers 130 may be arranged in steps (e.g., may be offset from each other in plan view) in a direction toward the corner portion DA2 of the display area DA with respect to the first gate driver 130a.

The first pixel circuit unit PC1, which corresponds to, and is electrically connected to, the first display element DPE1 arranged in the corner portion DA2 of the display area DA, may be electrically connected to the gate driver 130a or 130b apart therefrom in a first direction (e.g., a direction x). For example, the first pixel circuit unit PC1 may be electrically connected to the gate driver 130a or 130b that is closest of the plurality of gate drivers 130 apart therefrom in the first direction (e.g., the direction x). For example, the 1st-1 pixel circuit unit PC1-1 corresponding to the 1st-1 display element DPE1-1 may be electrically connected to the first gate driver 130a that is closest of the plurality of gate drivers 130 apart therefrom in the first direction (e.g., the direction x).

When the plurality of gate drivers 130, which are electrically connected to the plurality of first pixel circuit units PC1 corresponding to the plurality of first display elements DPE1 arranged in the corner portion DA2 of the display area DA, are arranged in steps in the connection portion DA3 and the corner portion DA2 of the display area DA, then the plurality of gate drivers 130, which are configured to provide a signal to the plurality of first pixel circuit units PC1, may be arranged in the display area DA as a panel embedded type, and accordingly, an area for an image to be displayed on a display device may be enlarged to improve the quality and reliability of a display device.

In addition, a distance d1 between the first gate driver 130a, which is arranged at an uppermost part of the connection portion DA3 and the corner portion DA2 of the display area DA, and the 1st-1 pixel circuit unit PC1-1 adjacent thereto and electrically connected thereto and the corresponding 1st-1 display element DPE1-1, and a distance d2 between the gate driver 130b, which is arranged below the first gate driver 130a and the first pixel circuit unit PC1 adjacent thereto, and the corresponding first display element DPE1 may be constant, and the output of pixel circuit units PC arranged in the corner portion DA2 may be stable.

According to one or more of the above embodiments, a display device with improved quality and reliability may be implemented. However, one or more embodiments are not limited by such an aspect.

It should be understood that embodiments described herein should be considered in a descriptive sense only and not for purposes of limitation. Descriptions of aspects within each embodiment should typically be considered as available for other similar aspects in other embodiments. While one or more embodiments have been described with reference to the figures, it will be understood by those of ordinary skill in the art that various changes in form and details may be made therein without departing from the spirit and scope as defined by the following claims, with functional equivalents thereof to be included therein.

What is claimed is:

1. A display device comprising:
a substrate comprising a display area comprising a corner portion, a connection portion, and a central portion, and a peripheral area surrounding at least a portion of the display area in plan view;
a first display element in the corner portion;
a second display element in the connection portion;
a first pixel circuit unit in the corner portion, and electrically connected to the first display element;
a second pixel circuit unit in the connection portion, and electrically connected to the second display element; and
gate drivers arranged in a line along a first direction, a gate driver of the gate drivers being in the connection portion, overlapping at least a portion of the second pixel circuit unit, and electrically connected to the first pixel circuit unit.

2. The display device of claim 1, wherein the first pixel circuit unit and the gate driver are spaced apart in a second direction crossing the first direction.

3. The display device of claim 2, wherein the gate driver is closest to the first pixel circuit unit of the gate drivers.

4. The display device of claim 1, wherein the first pixel circuit unit and the second pixel circuit unit are at a layer above the gate driver.

5. The display device of claim 1, wherein the first display element is provided in plurality, the first display elements comprising a 1st-1 display element at an uppermost part of the corner portion.

6. The display device of claim 5, wherein the first pixel circuit unit is provided in plurality, the first pixel circuit units comprising a 1st-1 pixel circuit unit at the uppermost part of the corner portion, and electrically connected to the 1st-1 display element.

7. The display device of claim 6, wherein the gate drivers comprise a first gate driver at an uppermost part of the connection portion, and electrically connected to the 1st-1 pixel circuit unit.

8. The display device of claim 7, wherein the gate drivers are aligned in the first direction.

9. The display device of claim 1, further comprising a clock line overlapping the gate drivers, and extending in the first direction.

10. The display device of claim 9, wherein the clock line is configured to electrically connect the gate drivers to each other.

11. The display device of claim 1, wherein the gate driver is electrically connected to the second pixel circuit unit.

12. The display device of claim 1, wherein the connection portion is between the corner portion and another corner portion of the display area, and
wherein the central portion of the display area is inside the corner portion and the connection portion.

13. A display device comprising:
a substrate comprising a display area comprising a corner portion, a connection portion, and a central portion, and a peripheral area surrounding at least a portion of the display area in plan view;
a first display element in the corner portion;
a second display element in the connection portion;
a first pixel circuit unit in the corner portion, and electrically connected to the first display element;
a second pixel circuit unit in the connection portion, and electrically connected to the second display element; and
gate drivers arranged in a first direction, respectively offset from one another in a direction from the connection portion toward the corner portion, and comprising a gate driver in the connection portion, overlapping at least a portion of the second pixel circuit unit, and electrically connected to the first pixel circuit unit.

14. The display device of claim 13, wherein the gate driver is closest to the first pixel circuit unit of the gate drivers in a second direction crossing the first direction.

15. The display device of claim 13, wherein the first display element is provided in plurality, the first display elements comprising a 1st-1 display element at an uppermost part of the corner portion.

16. The display device of claim 15, wherein the first pixel circuit unit is provided in plurality, the first pixel circuit units comprising a 1st-1 pixel circuit unit at the uppermost part of the corner portion, and electrically connected to the 1st-1 display element.

17. The display device of claim 16, wherein the gate drivers comprise a first gate driver at an uppermost part of the connection portion, and electrically connected to the 1st-1 pixel circuit unit.

18. The display device of claim 17, wherein the gate drivers are respectively offset in a direction toward the corner portion with respect to the first gate driver.

19. The display device of claim 14, further comprising a clock line overlapping the gate drivers, having a stepped shape in plan view, and configured to electrically connect the gate drivers to each other.

20. An electronic device comprising a display device comprising:
a substrate comprising a display area comprising a corner portion, a connection portion, and a central portion, and a peripheral area surrounding at least a portion of the display area in plan view;
a first display element in the corner portion;
a second display element in the connection portion;
a first pixel circuit unit in the corner portion, and electrically connected to the first display element;
a second pixel circuit unit in the connection portion, and electrically connected to the second display element; and
gate drivers arranged in a line along a first direction, a gate driver of the gate drivers being in the connection portion, overlapping at least a portion of the second pixel circuit unit, and electrically connected to the first pixel circuit unit.
